(19) United States
(12) Patent Application Publication
(10) Pub. No.: US 2005/0228940 A1
(43) Pub. Date: Oct. 13, 2005

(54) Device and method for recording information with characteristic point information control

(75) Inventors: Johannis Friso Rendert Blacquiere, Eindhoven (NL); Declan Patrick Kelly, Eindhoven (NL)

Correspondence Address: Philips Electronics North America Corporation;Corporate Patent Counsel, PO Box 3001, Briarcliff Manor, NY, 10510, US

(73) Assignee: Koninklijke Philips Electronics N.V., 5621 BA Eindhoven (NL)

(21) Appl. No.: 10/514,283

(22) PCT Filed: Apr. 22, 2003
(86) PCT No.: PCT/IB03/01574

§ 371 Date: Nov. 12, 2004

(30) Foreign Application Priority Data
May 17, 2002 (EP) 02076947

(51) Int. Cl. G11C 5/00

(52) U.S. Cl. 711/112; 711/4

(57) ABSTRACT

A device for recording digitally encoded video information records video packets and characteristic point information for controlling the playback of the packets. The device has an error detection unit (32) for detecting recording errors, and the size of a missing part of the real-time information due to a detected error. The characteristic point information can be used for detecting errors by verifying the accessibility of the video packets. An exit point before the detected error and an entry point after the detected error are determined, such that the video information up to the exit point and starting at the entry point constitute decodable streams of packets. Further the device has a recalculating unit (31) for recalculating, in the event of a detected recording error, the characteristic point information (CPI) by skipping packets between the exit point and the entry point.

The invention relates to a device for recording information in a track on a record carrier, which device comprises recording means for recording marks representing the information, control means for controlling recording of digitally encoded real-time information, in particular video, in a stream of packets in the track and of characteristic point information for controlling playback of the packets.

The invention further relates to a method of recording information.

The invention further relates to a computer program product for recording information.

A device and method for recording information on a record carrier are the known from WO 00/28544 (PHN 17161), in which digitally compressed video data is recorded on an optical disc according to a video encoding standard, for example the MPEG2 format. The apparatus has input means for receiving video information, and recording means for recording the video information in a stream of packets in the track, in particular in a video file. The packets may contain video, audio or other information, e.g. subtitles. A number of packets together are required to constitute a reproducible amount of information, e.g. a complete independently coded video frame called I-picture in MPEG. The device further has control means for generating characteristic point information for controlling playback of the packets. The characteristic point information identifies a characteristic point in the video file, i.e. locations of particular data elements such as start of an I-picture or a new scene. The characteristic point information includes pointers to addresses and/or pointers including an offset from a given reference point in the video file, e.g. the start of the file. A problem of the known system is that errors in the recorded data may occur, and that the reproduced video may be affected by the errors. In particular artifacts may be visible because the video decoder receives data not compliant with the applicable video standard.

It is an object of the invention to provide a system for recording and reproducing digitally compressed video information, which is able to hide errors in a more flexible way.

For this purpose, the device as described in the opening paragraph has error detection means for detecting recording errors and for detecting the size of a missing part of the real-time information due to a detected error and for determining an exit point before the detected error and an entry point after the detected error, the real-time information up to the exit point and starting at the entry point constituting decodable streams of packets, and recalculating means for recalculating, in the event of a detected recording error, the characteristic point information by skipping packets between the exit point and the entry point. The method comprises controlling recording of digitally encoded real-time information, in particular video, in a stream of packets in a track and of characteristic point information for controlling playback of the packets, detecting recording errors and detecting the size of a missing part of the real-time information due to a detected error and determining an exit point before the detected error and an entry point after the detected error, the real-time information up to the exit point and starting at the entry point constituting decodable streams of packets, and recalculating, in the event of a detected recording error, the characteristic point information by skipping packets between the exit point and the entry point. The measures have the advantage that recording errors, once detected, can be hidden by adapting the characteristic point information so that the erroneous parts are skipped. In particular the exit point is determined before the erroneous part and on a point in the stream of packets where the decoder has completed a picture. The entry point after the error is determined on a point in the stream from which the decoder can start decoding independently of any preceding information, e.g. an I-picture. Any packets, which are not affected by the detected error, but are part of a video picture that is affected, are skipped. Hence during such subsequent reproduction the error can be completely circumvented, because using the adapted characteristic point information the part of the video stream containing the error is no longer needed. In addition more complicated types of errors, which might result in a decoder reset, undefined audio and/or video data elements leading to visible or audible artifacts, are eliminated by adapting the characteristic point information. The resulting stream may still have a time discontinuity, which is however hardly detectable for the user.

The invention is also based on the following recognition. The inventors have seen that an inconsistency might occur between the characteristic point information and the video data that is actually on disc. There are (at least) the following three different kinds of situations that may lead to that situation. The medium contains no corrupt sectors on the areas considered, but part of the data is not written to disc. This could be a result of mechanical shocks, bad buffer management, a network error in case the disc drive is used as a network drive, etc. Secondly the medium contains corrupt sector(s) on the areas considered. During writing a corrupt sector is encountered and part of the data is lost. Thirdly a disc error is introduced some time after the data has been written correctly, e.g. due to scratches or dirt. Reducing the detrimental effect of the recording error can be achieved by solving the inconsistency. The CPI structure, generated to address the file, is used to check if the file was written correctly. If not, the CPI structure is used to find the part of the file that is missing. The characteristic point information is recalculated to be consistent with the data on disc.

In an embodiment of the device the error detection means comprise means for verifying the real-time information via the characteristic point information. This has the advantage that the characteristic point information constitutes a concise set of accessing information having access points distributed over the real-time information file. Further the characteristic point information indicates the size and location of the real-time information in addition to the file management system data. Using the characteristic point information gives an easy access to relevant packets within the video stream. Any detected error can be repaired by adapting the characteristic point information. In an embodiment said means for verifying are for verifying status information of a file of real-time information, in particular the file size or parts not written correctly as indicated by a file management system, and for determining missing parts of said file by accessing the file via the characteristic point information. This has the advantage that the file management system information may be available indicating that the file contains some errors, but not where and which parts of the file are missing. For real-time information the file may still be usable, and the characteristic point information is used to find which parts are normally accessible and which part are missing. Hence the damaged file can still be used with only a slight degradation of reproduced video quality.

In an embodiment of the device the recalculation means comprise means for removing pointers to packets between the exit point up and the entry point, and/or recalculating offsets of pointers after the entry point. This has the advantage, that the characteristic point information now only points to valid addresses of useful packets within the video file.

It is noted that US 2001/0018727 A1 describes devices for recording video data via a file management system and accompanying characteristic point information called AV addresses. The file management system has the function of defect management, i.e. relocating data which is affected by recording errors during recording. Hence all video data is recorded, and the file management system keeps track of the location of defect areas. The characteristic point information (AV addresses) is not involved in defect management (see [1150-1158]). On the contrary the current invention relates to situations where the data is damaged or missing permanently, and provides a solution using the characteristic point information.

These and other aspects of the invention will be apparent from and elucidated further with reference to the embodiments described by way of example in the following description and with reference to the accompanying drawings, in which

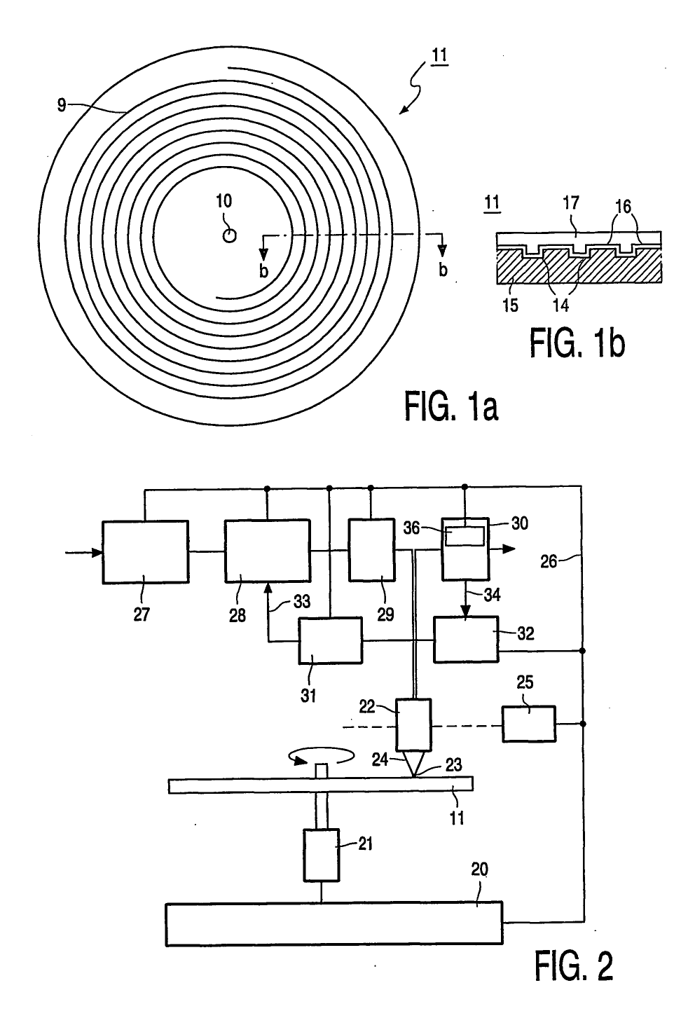

FIG. 1a shows a record carrier (top view),

FIG. 1b shows a record carrier (cross section),

FIG. 2 shows a recording device,

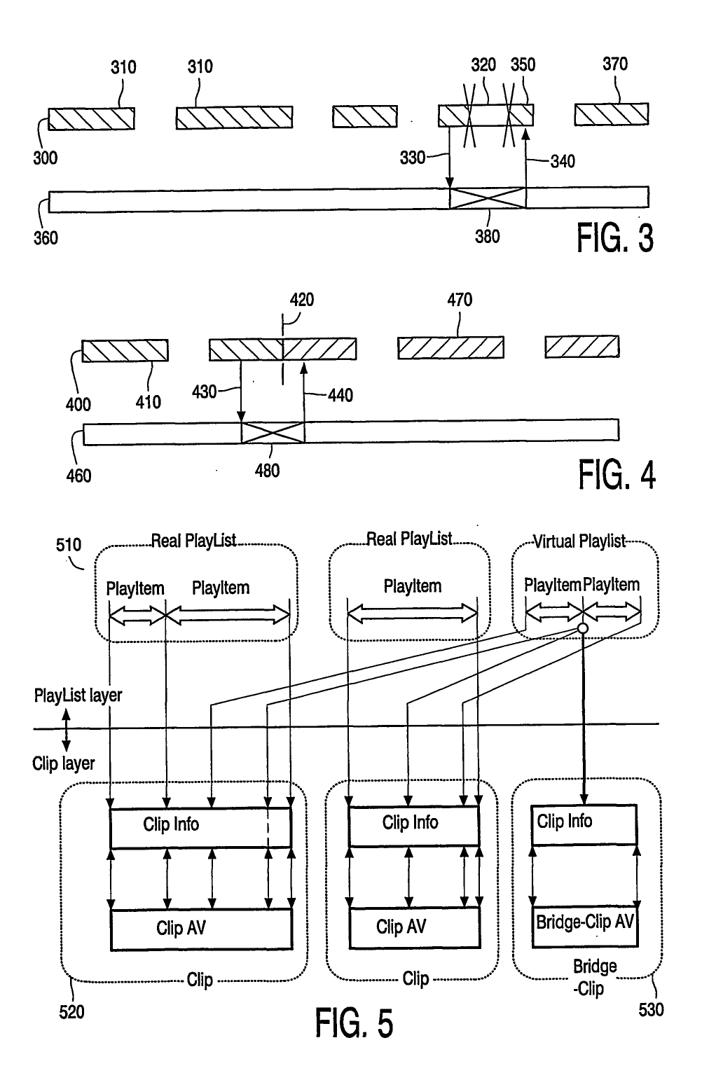

FIG. 3 shows extents of recorded video having a recording error and characteristic point information,

FIG. 4 shows extents of recorded video having a logical error and characteristic point information,

FIG. 5 shows characteristic point information and playlist information,

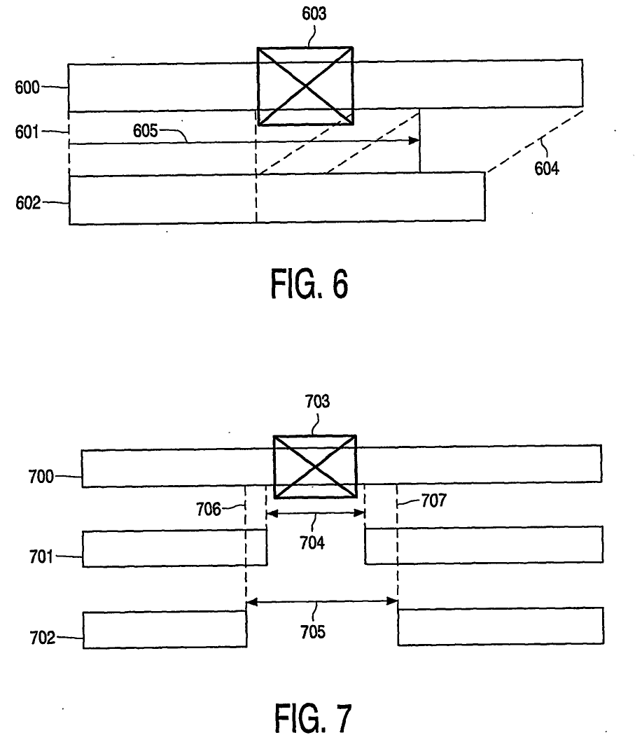

FIG. 6 shows recalculating offsets in characteristic point information, and

FIG. 7 shows skipping packets in characteristic point information.

Corresponding elements in different Figures have identical reference numerals.

FIG. 1a shows a disc-shaped record carrier 11 having a track 9 and a central hole 10. The track 9, being the position of the series of (to be) recorded marks representing information, is arranged in accordance with a spiral pattern of turns constituting substantially parallel tracks on an information layer. The record carrier may be optically readable, called an optical disc, and has an information layer of a recordable type. Examples of a recordable disc are the CD-R and CD-RW, and writable versions of DVD, such as DVD+RW, and the high density writable optical disc using blue lasers, called Blue-ray Disc (BD). Further details about the DVD disc can be found in reference: ECMA-267: 120 mm DVD—Read-Only Disc—(1997). The information is represented on the information layer by recording optically detectable marks along the track, e.g. crystalline or amorphous marks in phase change material. The track 9 on the recordable type of record carrier is indicated by a pre-embossed track structure provided during manufacture of the blank record carrier. The track structure is constituted, for example, by a pregroove 14 which enables a read/write head to follow the track during scanning. The track structure comprises position information, e.g. addresses, for indication the location of units of information, usually called information blocks. The position information includes specific synchronizing marks for locating the start of such information blocks. The position information is encoded in frames of modulated wobbles as described below.

FIG. 1b is a cross-section taken along the line b-b of the record carrier 11 of the recordable type, in which a transparent substrate 15 is provided with a recording layer 16 and a protective layer 17. The protective layer 17 may comprise a further substrate layer, for example as in DVD where the recording layer is at a 0.6 mm substrate and a further substrate of 0.6 mm is bonded to the back side thereof. The pregroove 14 may be implemented as an indentation or an elevation of the substrate 15 material, or as a material property deviating from its surroundings.

The record carrier 11 is intended for carrying information representing digitally encoded video according to a standardized format like MPEG2.

FIG. 2 shows a recording device for writing information on a record carrier 11 of a type which is writable or re-writable, for example CD-R or CD-RW, or DVD+RW or BD. The device is provided with recording means for scanning the track on the record carrier which means include a drive unit 21 for rotating the record carrier 11, a head 22, a positioning unit 25 for coarsely positioning the head 22 in the radial direction on the track, and a control unit 20. The head 22 comprises an optical system of a known type for generating a radiation beam 24 guided through optical elements focused to a radiation spot 23 on a track of the information layer of the record carrier. The radiation beam 24 is generated by a radiation source, e.g. a laser diode. The head further comprises (not shown) a focusing actuator for moving the focus of the radiation beam 24 along the optical axis of said beam and a tracking actuator for fine positioning of the spot 23 in a radial direction on the center of the track. The tracking actuator may comprise coils for radially moving an optical element or may alternatively be arranged for changing the angle of a reflecting element. For writing information the radiation is controlled to create optically detectable marks in the recording layer. For reading the radiation reflected by the information layer is detected by a detector of a usual type, e.g. a four-quadrant diode, in the head 22 for generating a read signal and further detector signals including a tracking error and a focusing error signal for controlling said tracking and focusing actuators. The read signal is processed by read processing unit 30 of a usual type including a demodulator, deformatter and output unit to retrieve the information. Hence retrieving means for reading information include the drive unit 21, the head 22, the positioning unit 25 and the read processing unit 30. The device comprises write processing means for processing the input information to generate a write signal to drive the head 22, which means comprise an input unit 27, and modulator means comprising a formatter 28 and a modulator 29. The control unit 20 controls the recording and retrieving of information and may be arranged for receiving commands from a user or from a host computer. The control unit 20 is connected via control lines 26, e.g. a system bus, to said input unit 27, formatter 28 and modulator 29, to the read processing unit 30, and to the drive unit 21, and the positioning unit 25. The control unit 20 comprises control circuitry, for example a microprocessor, a program memory and control gates, for performing the procedures and functions according to the invention as described below. The control unit 20 may also be implemented as a state machine in logic circuits. The input unit 27 processes the audio and/or video to unit of information, which are passed to the formatter 28 for adding control data and formatting the data according to the recording format (as described below), e.g. by adding error correction codes (ECC) and/or interleaving. For computer applications units of information may be interfaced to the formatter 28 directly. The formatted data from the output of the formatter 28 is passed to the modulation unit 29, which comprises for example a channel coder, for generating a modulated signal which drives the head 22. Further the modulation unit 29 comprises synchronizing means for including synchronizing patterns in the modulated signal. The formatted units presented to the input of the modulation unit 29 comprise address information and are written to corresponding addressable locations on the record carrier under the control of control unit 20. The control unit 20 is arranged for recording and retrieving position data indicative of the position of the recorded information volumes. During the writing operation, marks representing the information are formed on the record carrier. The marks may be in any optically readable form, e.g. in the form of areas with a reflection coefficient different from their surroundings, obtained when recording in materials such as dye, alloy or phase change material, or in the form of areas with a direction of magnetization different from their surroundings, obtained when recording in magneto-optical material. Writing and reading of information for recording on optical disks and usable formatting, error correcting and channel coding rules are well-known in the art, e.g. from the CD system. The marks can be formed by means of the spot 23 generated on the recording layer via the beam 24 of electromagnetic radiation, usually from a laser diode. User real-time information is presented on the input unit 27, which may comprise of compression means for input signals such as analog audio and/or video, or digital uncompressed audio/video. Suitable compression means are described for audio in WO 98/16014-A1 (PHN 16452), and for video in the MPEG2 standard. The input signal may alternatively be already encoded.

MPEG is a video signal compression standard, established by the Moving Picture Experts Group (“MPEG”) of the International Standardization Organization (ISO). MPEG is a multistage algorithm that integrates a number of well known data compression techniques into a single system. These include motion-compensated predictive coding, discrete cosine transform (“DCT”), adaptive quantization, and variable length coding (“VLC”). The main objective of MPEG is to remove redundancy which normally exists in the spatial domain (within a frame of video) as well as in the temporal domain (frame-to-frame), while allowing inter-frame compression and interleaved audio. MPEG-1 is defined in ISO/IEC 11172 and MPEG-2 is defined in ISO/IEC 13818. There are generally three different encoding formats which may be applied to video data. Intra-coding produces an “I” block, designating a block of data where the encoding relies solely on information within a video frame where the macro block 16 of data is located. Inter-coding may produce either a “P” block or a “B” block. A “P” block designates a block of data where the encoding relies on a prediction based upon blocks of information found in a prior video frame (either an I-frame or a P-frame, hereinafter together referred to as “reference frame”). A “B” block is a block of data where the encoding relies on a prediction based upon blocks of data from at most two surrounding video frames, i.e., a prior reference frame and/or a subsequent reference frame of video data. In principle, in between two reference frames (I-frame or P-frame) several frames can be coded as B-frames. However, since the temporal differences with the reference frames tend to increase if there are many frames in between (and consequently the coding size of a B-frame increases), in practice MPEG coding is used in such a way that in between reference frames typically at most two B frames are used, each depending on the same two surrounding reference frames. To eliminate frame-to-frame redundancy, the displacement of moving objects in the video images is estimated for the P-frames and B-frames, and encoded into motion vectors representing such motion from frame to frame. An I-frame is a frame wherein all blocks are inter-coded. A P-frame is a frame wherein the blocks are inter-coded as P-blocks. A B-frame is a frame wherein the blocks are inter-coded as B-blocks. If no effective coding inter-coding is possible for all blocks of a frame, some blocks may be inter-coded as a P-block or even as an I-block. Similarly, some blocks of a P-frame may be coded as I-blocks.

The device comprises error detection means for detecting recording errors. The control unit 20 is arranged for controlling recording of digitally encoded real-time information, in particular video, in a stream of packets in the track and of characteristic point information (CPI) for controlling playback of the packets. CPI is described in detail in WO 00/28544. Further the control unit 20 is arranged for detecting the recording errors in cooperation with the input unit 27, the read processing unit 30 and/or error detection unit 32. It is noted that the error detection means may be arranged for detecting errors during recording, but they are in particular arranged for detecting errors after the recording has taken place at some later time. In both cases we assume that correction of the video data or re-recording is not viable, i.e. the errors are considered to be permanent. The device is equipped to reduce the detrimental effects of such permanent errors. The device further comprises a recalculation unit 31 for recalculating the characteristic point information in the event of a detected recording error by skipping packets between the exit point and the entry point. The recalculation unit 31 has an output 33 coupled to the formatter 28 for supplying the recalculated characteristic point information to be recorded. The error detection unit 32 is arranged for selecting an exit point at the last possible point before the error location based on the type of encoding, e.g. exiting just before a new independently coded video frame (I-picture). Further the recalculation unit 31 is arranged for selecting an entry point at the first possible point after the error location and also based on the type of encoding, e.g. just before an I-picture.

The control unit 20 and error detection unit 32 are arranged for processing as follows. After a recording error has been detected, the size of a missing part of the real-time information is detected using the characteristic point information. For example a mismatch is detected between the length indicated in the CPI table and the file system length information. Then an exit point before the detected error and an entry point after the detected error are determined. The exit and entry point are selected such that the skipped part of the video stream is as small as possible, while the real-time information up to the exit point and starting at the entry point both constitute a decodable stream of packets. The characteristic point information and further references to the video data are recalculated marking the discontinuity as a discontinuity of time and updating pointers and the relevant tables.

In an embodiment of the device the control unit and the functions of error detection and recalculation of characteristic point information are implemented in a software program. The software program running in suitable computer environment is controlling the execution of the recording process in a disc drive unit which is connected to the computer, e.g. an optical disc recorder coupled via an interface bus or network to a PC.

FIG. 3 shows extents of recorded video having a recording error and characteristic point information. Schematically an encoded video signal 300 is shown as a series of extents 310 recorded along a track of the record carrier, each extent being a recording area containing a stream of packets and having a minimum size as defined in the applicable recording standard. An extent may also be a large part of the disc, and contain a substantial amount of video information, e.g. a movie. Further the Figure shows characteristic point information 360, depicted as a single file of control information for accessing the video information blocks in the extents, e.g. pointers to the reproducible stream of actual real-time information 300 as contained in the extents 310. At an error location 320 a recording error is detected, e.g. by a physical damaged part of the track no information has been recorded or is not accessible any more. The last part 350 of the extent and the next extent 370 are normally accessible. The error is detected and the characteristic point information is recalculated to exclude a missing part 380. It is determined that the encoded video is reproducible up to an exit point 330 and continues to be reproducible at an entry point 340. The entry point 340 may also be at the start of the next extent 370, if the last part 350 does not contain useful information. The characteristic point information and playback control information is described in detail below with reference to FIGS. 5, 6 and 7. Further the control unit 20 is arranged for recording the recalculated characteristic point information.

In an embodiment of the device the error detection unit 32 is coupled to the read processing unit 30 via an error output 34 for detecting physical errors, e.g. during writing or reading information on the record carrier 11. The read signals from the record carrier are monitored for detecting a physical defect of the record carrier. Detecting such defects can be based on the reflected laser radiation during writing an optical disc, or on detecting deviations in other writing parameters. For example a read signal can be generated and errors occurring can be detected by the usual error correction codes (ECC) embedded in the data blocks recorded.

In an embodiment the error detection unit 32 is arranged for detecting errors by reading and processing defect information recorded earlier on the record carrier, e.g. defect tables managed by a file management system like UDF. By analyzing the defect information the write error detection unit detects an erroneous location or possibly erroneous locations. For example the file management system creates an Alarm List of locations that show a relatively high number of errors. If the video information is recorded in such a location, the characteristic point information is used to verify the accessibility of the video information in that area. If some video information cannot be accessed, the characteristic point information is recalculated skipping the un-accessible part.

Detecting recording errors can be based on other status information from the file system. The file system usually will be aware of the loss of data when recording and update its file tables to reflect this, e.g. typically a write request will return the number of bytes written so the file system will know how many bytes were lost (but not which ones). In some cases the file system indicates the parts of the file that were lost. In this case the data before and after the last part can be read to determine what data in terms of time was lost. Alternatively the drive may just indicate that the write did not complete. However, in some cases the file system may be consistent with the disc but not with the application layer e.g. in case of networked storage where some data was lost over the network. The characteristic point information can be used to verify such consistency.

In a practical embodiment the file system must be made consistent with the data actually written on disc as follows. In the case where the file system received an ‘action not complete’ event from the drive it may be necessary to read back the data to find the parts that were successfully written. It will be possible to find discontinuities by parsing the stream or looking at invalid ECC blocks. After the file system has been updated to reflect the actual data on disc, there are two further problems to be addressed. First, addressing is done using source packet offsets i.e. the file content is addressed in multiples of the source packet size, in this case 192 bytes. This means that the size of lost data must be a multiple of 192 bytes in order for the addressing to work (otherwise the source packet offsets will not point to the start of source packets). Therefore the file system should be updated to make the lost data a multiple of the source packet size. It is to be verified that the missing data is actually an integral number of full source packets (and not just a multiple of the source packet size). This ensures that the file doesn't include any partial source packets.

FIG. 4 shows extents of recorded video having a logical error and characteristic point information. Schematically an encoded video signal 400 is shown as a series of extents 410 recorded along a track of the record carrier, each extent containing a stream of packets. Further the Figure shows characteristic point information 460 depicted as a single file of control information for accessing the video information blocks in the extents 400. At an error location 420 a logical error occurs, e.g. by a missing part of video information in the input video stream. The next extent 470 has been recorded normally. The error is detected and the characteristic point information is recalculated to exclude a missing part 480. It is determined that the encoded video is reproducible up to an exit point 430 and continues to be reproducible at an entry point 440. The exit point 430 and the entry point 440 are located both in the same extent, and may be very close with this type of logical error.

In an embodiment of the device the control unit 20 is arranged for performing a repair function for video information recorded earlier. The error detection means comprise a video stream error detection unit 36 coupled to the read processing unit 30. The video stream as recorded is reproduced, and recording errors are detected. The characteristic point information is recalculated and recorded as described above. The video stream error detection unit 36 may be implemented as a function of the MPEG2 video decoder, which decoder necessarily has to process the video data and therefore can easily be adapted to provide error detection of inconsistent video data.

FIG. 5 shows playback information. The playback information is shown in the upper part called playlist layer, while the video stream information is shown in the lower part called clip layer. A Playlist 510 is a collection of presentation intervals of video, which video stream is physically stored in a Clip 520. The Clip comprises Clip Info files which comprise the characteristic point information for reproducing a continuous amount of video as recorded in a recording session, and the Clip AV files contain the video and audio information itself. For example the characteristic point information comprises address information about access points in the Clip AV file, usually on time stamp basis. In the playlist layer there is shown a first type of file structure, the Real Playlist, which controls the playback of a single recorded clip. The clip may be subdivided in the Playlist in a number of PlayItems defining the presentation intervals. There is no need that Playitems are physically consecutive, e.g. commercials in a recorded video stream may be skipped by making them into unselected PlayItems. The Real Playlist is coupled directly to the corresponding Clip, e.g. if the Real playlist is deleted the Clip is also deleted, provided the clip is not linked to a Virtual playlist. The second type of file structure, the Virtual Playlist, is used to control playback of presentation intervals from several Clips, and/or from a Bridge-Clip 530, which is specifically created for making a seamless connection between when switching from a PlayItem in one Clip to a next PlayItem in a different Clip. According to the invention a detected error is prevented by recalculating the characteristic point information as described above. In an embodiment the corresponding playback information is also recalculated, because the part now skipped in the characteristic point information cannot be accessed anymore.

In an embodiment the error detection and characteristic point information recalculation process can be controlled by a user. The user detects errors in the digitally encoded video information, for example glitches or artifacts in the displayed video stream. The device has a user command mode in which the user then indicates which part of the video must be marked as a recording error. The device then recalculates the characteristic point information as described above.

FIG. 6 shows recalculating offsets in characteristic point information. Original file data 600 is drawn on top having a size as it should have been recorded. The characteristic point information 601 is indicated is indicated as dashed lines pointing to characteristic items in the video file. The original characteristic point information is schematically indicated by vertical lines. For example a specific pointer in the characteristic point information 601 has an offset 605. However, a recording error 603 results in a part of the file not being recorded (or being not accessible). The actual video file 602 is indicated at the bottom of the Figure. Due the error 603 and the missing part, the actual file size is smaller and the offset is set to an incorrect location. Knowing the size of the missing part the characteristic point information is recalculated, e.g. the recalculation of pointers and offset is indicated by the slanted dashed lines 604. The characteristic point information (CPI) can be used to detect errors. If the last point in CPI addresses a location that is past the end of the file then it is clear that part of the file data has been lost. In this case the CPI can be used to detect the part of the file that is missing. This can be done using a binary search through the CPI table looking for the first entry where the data on disc at the location pointed to by the CPI entry does not correspond to the packet with the same presentation time stamp (PTS) as in the CPI entry. Once this point is found in the file, the next PTS after the discontinuity indicates where the valid data resumes. Using these two PTSs the amount of data missing in terms of presentation time can be calculated. It is possible that there are multiple parts of the file missing but they can each be found by searching as above. The CPI must be updated to reflect the errors. This involves removing the CPI that points to missing data and updating CPI pointers to addresses after the first error in that stream. Once the missing data is known the application structures can be updated to reflect the errors (see FIG. 5). A received data transport stream usually will contain time indicators, e.g. an arrival time clock (ATC) indicating the timing of packets within the transport stream. When during recording some data is lost, there will be an ATC discontinuity. The clip information will be updated to indicate an ATC discontinuity at the point where the defect occurs and the CPI for the missing data will be discarded. The addresses of all points after the ATC discontinuity should be updated to reflect the changes.

FIG. 7 shows skipping packets in characteristic point information. Original file data 700 is drawn on top having a size as it should have been recorded. However, a recording error 703 results in a part of the file not being recorded (or being not accessible). In a first step the missing part due to error 703 is established by taking only complete source packets as described above with reference to FIG. 4. Hence in a file 701, adjusted for complete packets, the part 704 cannot be accessed for retrieving video packets. The second problem is that, although the remaining data is a sequence of complete source packets, the data will not in general decode correctly because of the coding dependencies between MPEG-2 frames. This will result in visible artefacts on playback. To avoid these artefacts some additional information should be discarded so that the video can be decoded correctly. This means finishing the sequence before the defect at an exit point 706 just before an I- or P-frame and starting the sequence at an entry point 707 after the defect with an I-frame. The result is that instead of visible artefacts caused by decoding errors, there will be an interruption 705 in the video presentation—this will be less disturbing to the user than decoding errors. It is noted that other alignments may be necessary as well, e.g. video data may be structured in units (like DVD in VOBU). Any incomplete structures, which cannot be reproduced, have to be cut off. The final file 702 as indicated by the recalculated characteristic point information is adjusted for picture decoding without visible problems.

Although the invention has been explained mainly by embodiments using the BD, similar embodiments like DVD are suitable for other optical recording systems. For example in the DVD+RW the playback information is organized according to the DVD standard as in said ECMA document, including Cells containing characteristic point information for reproducible items and VOBUs for physically stored video. Also for the information carrier an optical disc has been described, but other media, such as a hard disc or magnetic tape, can be used. It is noted, that in this document the word ‘comprising’ does not exclude the presence of other elements or steps than those listed and the word ‘a’ or ‘an’ preceding an element does not exclude the presence of a plurality of such elements, that any reference signs do not limit the scope of the claims, that the invention may be implemented by means of both hardware and software, and that several ‘means’ may be represented by the same item of hardware. Further, the scope of the invention is not limited to the embodiments, and the invention lies in each and every novel feature or combination of features described above.

1. Device for recording information in a track on a record carrier, which device comprises recording means for recording marks representing the information,
control means
for controlling recording of digitally encoded real-time information, in particular video, in a stream of packets in the track and of characteristic point information for controlling playback of the packets,
error detection means
for detecting recording errors and
for detecting the size of a missing part of the real-time information due to a detected error and
for determining an exit point before the detected error and an entry point after the detected error, the real-time information up to the exit point and starting at the entry point constituting decodable streams of packets, and
recalculating means
for recalculating, in the event of a detected recording error, the characteristic point information by skipping packets between the exit point and the entry point.

2. Device as claimed in claim 1, wherein the error detection means comprise means for verifying the real-time information via the characteristic point information.

3. Device as claimed in claim 2, wherein said means for verifying are for verifying status information of a file of real-time information, in particular status information from a file management system indicating the file size or parts not written correctly, and for determining missing parts of said file by accessing the file via the characteristic point information.

4. Device as claimed in claim 1, wherein the error detection means comprise means for detecting a record carrier error by retrieving defect information from the record carrier, which defect information indicates locations of error-prone parts of the track.

5. Device as claimed in claim 1, wherein the error detection means comprise means for detecting logical errors in the digitally encoded video information, or for detecting discontinuities in time indicators included in a continuous stream of digitally encoded video information, in particular a video decoder detecting data not in conformance with the applicable video encoding standard.

6. Device as claimed in claim 1, wherein the error detection means comprise means for receiving commands from a user for marking errors in the digitally encoded video information.

7. Device as claimed in claim 1, wherein the recalculation means comprise means for removing pointers to packets between the exit point up and the entry point, and/or recalculating offsets of pointers after the entry point.

8. Device as claimed in claim 1, wherein the control means comprise means for generating a playlist constituting a control structure of playback information for controlling the playback of a sequence of extents, an extent being a structure of recorded real time information, and for updating the playlist in dependence of the recalculation of the characteristic point information.

9. Method of recording information, which method comprises
controlling recording of digitally encoded real-time information, in particular video, in a stream of packets in a track and of characteristic point information for controlling playback of the packets,
detecting recording errors and
detecting the size of a missing part of the real-time information due to a detected error and
determining an exit point before the detected error and an entry point after the detected error, the real-time information up to the exit point and starting at the entry point constituting decodable streams of packets, and
recalculating, in the event of a detected recording error, the characteristic point information by skipping packets between the exit point and the entry point.

10. Computer program product for recording information, which program is operative to cause a processor to perform the method as claimed in claim 9.
